(19) United States
(12) Patent Application Publication
(10) Pub. No.: US 2025/0357354 A1
(43) Pub. Date: Nov. 20, 2025

(54) THROUGH-SILICON VIA PITCH TRANSLATION FOR STACKED MEMORY DEVICES

(71) Applicant: MICRON TECHNOLOGY, INC., BOISE, ID (US)

(72) Inventor: Sujeet Ayyapureddi, Boise, ID (US)

(73) Assignee: MICRON TECHNOLOGY, INC., Boise, ID (US)

(21) Appl. No.: 19/193,497

(22) Filed: Apr. 29, 2025

Related U.S. Application Data
(60) Provisional application No. 63/647,188, filed on May 14, 2024.

(51) Int. Cl. H01L 23/538; H01L 23/48; H01L 25/00; H01L 25/07

(52) U.S. Cl. CPC H01L 23/5385; H01L 23/481; H01L 25/071; H01L 25/50

(57) ABSTRACT

Apparatuses, systems, and methods for translating the through-silicon via (TSV) pitch. A stacked memory device may include a number of core dies stacked on an interface die that communicates between external devices and the core dies. This communication may occur using through-silicon vias (TSVs) that couple the core dies with each other and with the interface die. TSVs may also couple the interface die to external devices. In order for the dies to communicate, the terminals of the TSVs on the surface of a particular die must align with the terminals of the TSVs on the surface of the die to be stacked on to it. In this way, the TSVs create a continuous electrical coupling through the stack. A translator die may be used to couple the respective TSVs of a stacked die having a particular TSV pitch with another die having a different TSV pitch.

### CROSS-REFERENCE TO RELATED APPLICATIONS

This application claims the filing benefit of U.S. Provisional Application No. 63/647,188, filed May 14, 2024. This application is incorporated by reference herein in its entirety and for all purposes.

### BACKGROUND

This disclosure relates generally to semiconductor devices, such as semiconductor memory devices. A memory device may be a stacked memory device, in which a number of core dies, each containing a memory array are stacked on top of an interface die. The interface die may have terminals which connect to one or more external devices. The interface die may communicate with the core dies to perform various operations, such as read or write operations to the memory arrays in one or more of the core dies.

The core dies and interface die may be coupled by through silicon vias (TSVs). TSVs couple signals between each of the stacked dies and between the memory stack and the outside world. A stacked memory die may have multiple TSVs and the TSVs may have a spacing between them. Different semi-conductor devices may have different spacings of TSVs and/or external terminals which couple to the TSVs.

### BRIEF DESCRIPTION OF DRAWINGS

FIG. 1 is a block diagram of a semiconductor device according to at least one embodiment of the disclosure.

FIG. 2 is a block diagram of a memory package according to an embodiment of the present disclosure.

FIG. 3 is a block diagram of a memory package according to an embodiment of the present disclosure.

FIG. 4 is a block diagram of a memory package according to an embodiment of the present disclosure.

FIG. 5 is a block diagram of a memory package according to an embodiment of the present disclosure.

FIG. 6 is a flow chart of a method according to some embodiments of the present disclosure.

FIG. 7 is a flow chart of a method according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Directional terms like “up,” “down,” “vertical,” “horizontal,” and the like are all relative and meant to aid in understanding, but the embodiments described can be positioned in any orientation. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device may include a number of core dies, each including a memory array, stacked on an interface die that communicates between external devices and the core dies. This communication may occur using through-silicon vias (TSVs) that couple the core dies with each other and with the interface die. TSVs may also couple the interface die to external devices. For example, the TSVs may couple to external terminals on the interface die. The circuits of the core and interface die may generally be positioned on a surface of a substrate material, such as a silicon chip. The terms “die” and “chip” may be used interchangeably throughout. The TSVs may penetrate through the substrate material to allow signals to pass “vertically” through the stacked dies. In order for the dies to communicate, the terminals of the TSVs on the surface of a particular die must align with the terminals of the TSVs on the surface of the die to be stacked on to it. In this way, the TSVs create a continuous electrical coupling through the stack.

The TSVs of a particular die may have a particular spacing between them, or a particular TSV pitch. If the TSV pitch of one die is different than that of the die it is to be stacked upon, the TSVs will not align and there will not be a continuous electrical coupling through the stack with which to send communications to all dies. Different devices may use different TSV pitches. In order to make these devices compatible, there may be a need to translate between different TSV pitch sizes.

According to embodiments of the present disclosure, a translator die may be used to couple the respective TSVs of a stacked die having a particular TSV pitch with another die having a different TSV pitch. The translator die may have a set of TSVs with a TSV pitch that matches one of the dies to be stacked at the terminals or connection points on one surface of the translator die and the terminals on the opposite surface of the translator die may have a different TSV pitch that matches the TSV pitch of another die to be stacked. Thus, the TSVs create a continuous coupling through the translator die. In some embodiments, the translator die may be used to make devices made by different manufacturers compatible with each other. In some embodiments, the translator die may be a separate component added between otherwise unmodified devices to couple their TSVs. In some embodiments, the translator die may be integrated into one of the devices (e.g., the interface die may include the functionality of the translator die).

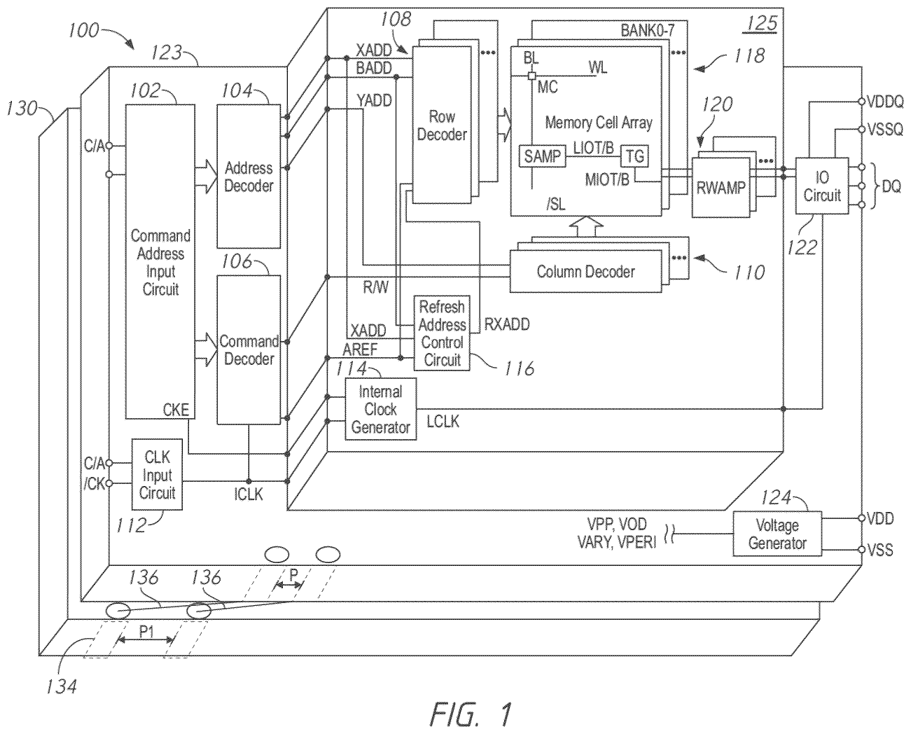

FIG. 1 is a block diagram of a semiconductor device according to at least one embodiment of the disclosure. The semiconductor device 100 may be a semiconductor memory device, such as a DRAM device integrated on a single semiconductor chip. The example device 100 of FIG. 1 includes a memory package such as the stack 125 of core dies positioned on an interface die 123, which may function as an interface between the core dies 125 and external devices, such as a host device (e.g., a processor). Although certain components are shown in the core dies of the stack 125, and certain components on the interface die 123, other arrangements of the components of the device 100 between the stack 125 and the interface die 123 are possible in other example embodiments. In some embodiments, the device 100 may include multiple stacks 125.

For brevity and clarity of illustration, only the components of one memory die in the memory stack 125 are shown in FIG. 1. Generally, the different dies of the stack 125 may each have similar components to each other. In some embodiments, each die of the stack 125 may be physically identical to each other. The stack 125 includes an interface die 123 that is coupled with a stack of one or more core dies 125. The interface die 123 may send and receive information (e.g., data, commands) to and from the outside, while the core dies in the stack 125 communicate with components of the interface die 123. As described herein, commands and other signals sent by the interface die 123 may be sent to all core dies in the stack 125 or may be separately addressed to individual core dies of the stack 125. The commands may be sent by way of through-silicon vias (TSVs) 134 coupling the core dies of the stack 125. The core dies of the stack 125 may be coupled to the interface die 123 with TSVs and the interface die 123 may be coupled to an external device (not shown) with TSVs. The distance between the TSVs, or TSV pitch, on the core dies of the stack 125 and the interface die 123 may be different than the distance between the connection points of the external device. In some examples, the TSV pitch of the core dies of the stack 125 may be different than the TSV pitch of the interface die 123 needed to couple the core dies of the stack 125 to the external device. In such cases, there may be a need for a translator die 130 to couple the respective TSVs of the core dies of the stack 125 and the interface die 123 with the connection points of the external device and/or the TSVs of the core dies of the stack 125 to the TSVs of the interface die 123.

The semiconductor device 100 includes a memory array 118. The memory array 118 may be positioned on a die of the memory stack 125. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 110. The row and column decoders 108 and 110 may also be positioned in the dies of the memory stack 125. In the embodiment of FIG. 1, the row decoder 108 includes a respective row decoder for each memory bank and the column decoder 110 includes a respective column decoder for each memory bank. The bit lines BL are coupled to a respective sense amplifier (SAMP). Read data from the bit line BL is amplified by the sense amplifier SAMP, and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bit line BL.

The semiconductor device 100 may employ a plurality of external terminals that include command and address (C/A) terminals coupled to a command and address bus to receive commands and addresses, and a CS signal, clock terminals to receive clocks CK and/CK, data terminals DQ to provide data, and power supply terminals to receive power supply potentials VDD, VSS, VDDQ, and VSSQ. The external terminals may be positioned on the interface die 123.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. In some embodiments, the address decoder 104 may also indicate a particular memory die of the memory stack 125 for activation. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The device 100 may receive an access command which is a read command. When a read command is received, and a bank address, a row address and a column address (and optional die address) are timely supplied with the read command, read data is read from memory cells in the memory array 118 corresponding to the row address and column address. The read command is received by the command decoder 106, which provides internal commands so that read data from the memory array 118 is provided to the read/write amplifiers 120. The read data is output to outside from the data terminals DQ via the input/output circuit 122.

The device 100 may receive an access command which is a write command. When the write command is received, and a bank address, a row address and a column address (and optional die address) are timely supplied with the write command, write data supplied to the data terminals DQ is written to a memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC.

The device 100 may also receive commands causing it to carry out refresh operation. The refresh signal AREF may be a pulse signal which is activated when the command decoder 106 receives a signal which indicates a refresh command. Responsive to the refresh signal AREF the device 100 may perform a refresh operation on some or all of the memory addresses.

The power supply terminals are supplied with power supply potentials VDD and VSS. The power supply potentials VDD and VSS are supplied to an internal voltage generator circuit 124. The internal voltage generator circuit 124 generates various internal potentials VPP, VOD, VARY, VPERI, and the like based on the power supply potentials VDD and VSS supplied to the power supply terminals. The internal potential VPP is mainly used in the row decoder 108, the internal potentials VOD and VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

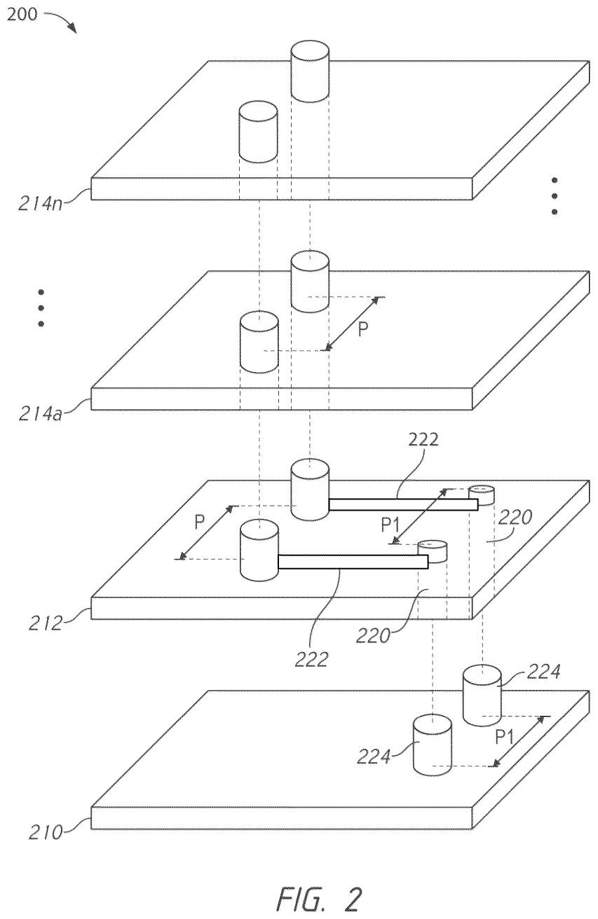

FIG. 2 is a block diagram of a stacked memory device according to an embodiment of the present disclosure. The stacked memory device 200 may be an example arrangement of the memory stack 125 of FIG. 1 in some embodiments. A first die 210 may comprise TSV connection points 224. In some embodiments, the first die 210 may be a memory die, such a core die (e.g., one of the core dies of stack 125 of FIG. 1) or an interface die (e.g., 123 of FIG. 1). In some embodiments, the first die 210 may be a host, such as a processor. In some embodiments, the first die 210 may be an interposer that connects an interface die (e.g., 123 of FIG. 1) to a host. The first die 210 may need to be stacked with other memory chips such as stacked dies 214a-214n containing TSVs 220 such that the TSV connection points 224 on the first die 210 and the TSVs 220 in the other stacked dies 214a-214n are aligned and thus, continuously coupled. In some embodiments, stacked die 214a may be an interface die (e.g., 123 of FIG. 1). In some embodiments, stacked die 214a may be a core die (e.g., one of the core dies of stack 125 of FIG. 1). Although the stacked memory device 200 shows a pair of dies 214a and 214n, more or fewer dies may be used in other embodiments.

The TSVs 220 may run vertically through the stacked memory device 200. The TSVs may run from a top surface of a die or chip 210, 212, or 214 to a bottom surface of the die or chip 210, 212, or 214. The upper portion of a given TSV 220 may couple to a corresponding lower portion of a TSV 220 in an adjacent die or chip 210, 212, or 214 up, and the lower portion of the TSV may couple to a corresponding upper portion of a TSV in another adjacent die or chip 210, 212, or 214 down in the stacked memory device 200. The TSV connection points 224 on the first die 210 or the TSVs of the stacked dies 214a-214n may be arranged such that they have a horizontal distance between them in the plane of the die, also called a TSV pitch. The stacked die TSV pitch P and/or the first die TSV pitch P1 may be measured from one TSV 220 to another TSV 220 (or from one TSV connection point 224 to another TSV connection point 224) on the same die. The TSV pitch may be measured from the center of one TSV 220 (or TSV connection point 224) to the center of another TSV 220 (or TSV connection point 224) on the same die. For example, the first die TSV pitch P1 may be measured from the center of one TSV connection point 224 to the center of another TSV connection point 224 on the first die 210. The TSV pitch P1 on the first die 210 may be different than the TSV pitch P of the TSVs 220 on the stacked dies 214a-214n. In order to continuously couple the TSVs 220 of the stacked dies 214a-214n with the TSV connection points 224 of the first die 210, a translator die 212 may be stacked between them. In some embodiments, the first die TSV pitch P1 may be wider than the stacked die TSV pitch P. In other embodiments, the first die TSV pitch P1 may be narrower than the stacked die TSV pitch P.

The translator die 212 may couple to the TSV connection points 224 of the first die 210 with TSV pitch P1 on one surface and with the TSVs 220 of the first stacked die 214a with a TSV pitch P on the opposite surface that is different from the first die TSV die pitch P1. The TSVs 220 may pass straight through the translator die 212 at the first chip TSV pitch P1 from the bottom surface to the top surface. Horizontal conductive traces 222 along the top surface of the translator die 212 may connect the TSVs 220 at the first chip TSV pitch P1 to TSVs 220 at the stacked die TSV pitch P. In some embodiments, the horizontal conductive traces 222 may be along the bottom surface of the translator die 212. In some embodiments, the translator die 212 could be placed between any two chips with differing TSV pitches such as between two stacked dies 214.

The electric coupling of the first die 210 TSV connection points 224 to the first stacked die 214a may be the only circuitry on the translator die 212. In some embodiments, the translator die 212 may be thinner than the first chip 210 and/or the stacked dies 214a-214n.

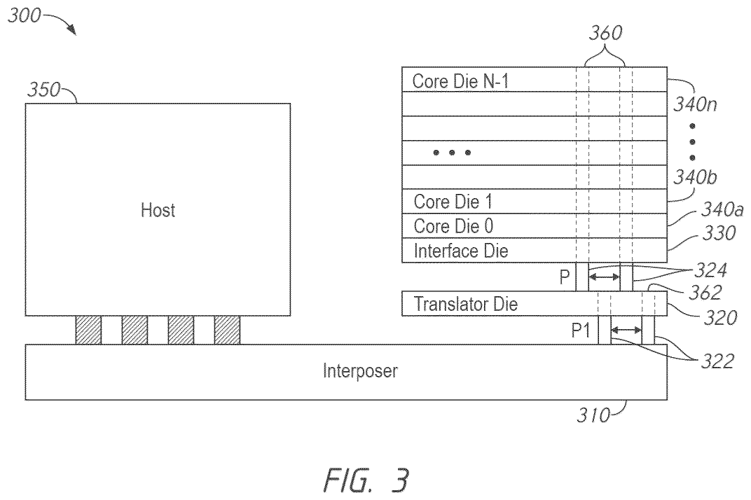

FIG. 3 is a block diagram of a memory package according to an embodiment of the present disclosure. The memory package 300 may be an implementation of the semiconductor device 100 and memory stack 125 of FIG. 1 in some embodiments. The memory package 300 may also be an implementation of the stacked memory device 200 of FIG. 2 in some embodiments.

The memory package 300 includes an interposer 310 which includes terminals (not shown in FIG. 3) that send and receive information to other components outside the memory package 300. In some examples, the memory package 300 may also include a host 350, such as a processor, electrically coupled to interface die 330 via the interposer 310. The host 350 may be stacked on the interposer 310 and adjacent to the stacked core dies 340. The interface die 330 may be an implementation of the interface die 123 of FIG. 1. The interface die 330 may be stacked between the stacked core dies 340 and the interposer 310. The interface die 330 may include TSVs 360 to electrically couple the interface die 320 to the stacked core dies 340. The stacked core dies 340 may be an implementation of the stacked dies 214 of FIG. 2 and/or the memory stack 125 of FIG. 1. Although FIG. 3 shows the memory package 300 with N core dies, labelled Core Die 0 to Core Die N−1, the stack may have any number of core dies, such as two core dies, 4 core dies, 8 core dies, or any other number.

In some embodiments, the interface die 330 may be coupled to the interposer 310 with TSVs 360. The TSVs 360 coupling the interface die 330 with the stacked core dies 340 may have a different TSV pitch than the TSVs 360 of the interposer 310. For example, the interface die 330 and/or the core die TSV pitch P may be narrower or wider than the interposer TSV pitch P1. The TSV pitches P and P1 of memory package 300 may be implementations of the TSV pitches P and P1 of FIG. 2 and/or FIG. 1. The difference in TSV pitches may require the use of a translator die 330. The translator die 330 may be an implementation of the translator die 212 of FIG. 2 and/or the translator die 130 of FIG. 1. The translator die 320 may be stacked between the interface die 330 and the interposer 310. The translator die 320 may couple to the interposer via TSV connection points 322 (e.g., 224 of FIG. 2) that have interposer TSV pitch P1 and pass the TSVs 360 through at the interposer TSV pitch P1. The translator die 320 may then change the TSV pitch to the interface die and/or stacked die TSV pitch P using horizontal conductive traces 362 along the top surface of the translator die 320 to align with TSV connection points 324. The conductive traces 362 may be an implementation of the conductive traces 222 of FIGS. 2 and/or 136 of FIG. 1. The memory package 300 may be an implementation of a side-by-side configuration sometimes called 2.5D memory packaging.

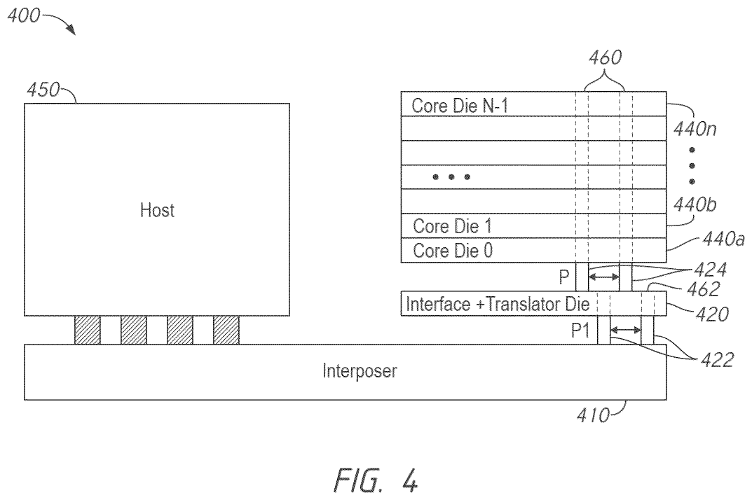

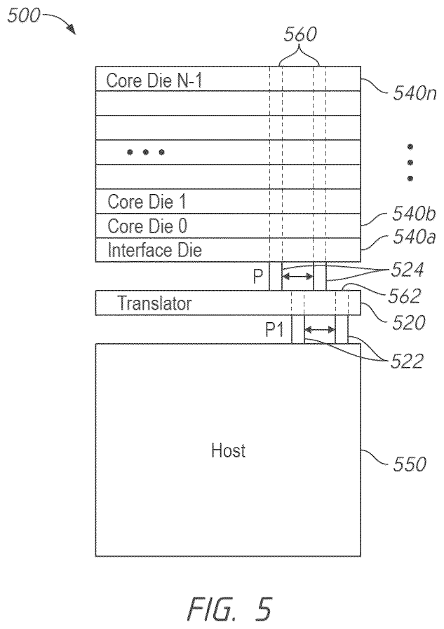

FIG. 4 is a block diagram of a memory package according to an embodiment of the present disclosure. The memory package 400 may be an implementation of the semiconductor device 100 and memory stack 125 of FIG. 1 in some embodiments. The memory package 400 may also be an implementation of the stacked memory device 200 of FIG. 2 in some embodiments. The embodiment of FIG. 4 may be generally similar to the embodiment of FIG. 5, except that in the memory package 400 of FIG. 4, the translator and interface die have been combined into an interface/translator die 420. The interface/translator die 420 may include both the functionality of the interface die as well as the TSV pitch changes of the interface die.

In some embodiments, the memory package 400 may include an interposer 410 such as the interposer 310 of FIG. 3, which includes terminals that send and receive information to other components outside the memory package 400. In some examples, the memory package 400 may also include a host 450, such as host 350 of FIG. 3, electrically coupled to an interface/translator die 420 via the interposer 410. The host 450 may be stacked on the interposer 410 and adjacent to the stacked core dies 440. The interface die 420 may be an implementation of the stacked die 214a of FIG. 2 and/or the interface die 123 of FIG. 1. The interface/translator die 420 may be stacked between the stacked core dies 440 and the interposer 410. The interface/translator die 420 may include TSVs 460 (e.g., 360 of FIG. 3, 220 of FIGS. 2, and/or 134 of FIG. 1) to electrically couple the interface/translator die 420 to the stacked core dies 440. The stacked core dies 440 may be an implementation of the stacked core dies 340 of FIG. 3, stacked dies 214 of FIG. 2, and/or the memory stack 125 of FIG. 1. Although FIG. 4 shows the memory package 400 with N core dies, labelled Core Die 0 to Core Die N−1, the stack may have any number of core dies, such as two core dies, 4 core dies, 8 core dies, or any other number.

The TSVs 460 coupling the interface/translator die 420 with the stacked core dies 440 may have a different TSV pitch in the interface/translator die 420 and/or stacked core dies 440 than in the interposer 410. For example, the stacked die TSV pitch P may be narrower or wider than the interposer TSV pitch P1. The TSV pitches P and P1 of memory package 400 may be implementations of the TSV pitches P and P1 of FIG. 3, FIG. 2, and/or FIG. 1. The difference in TSV pitches may require the use of a translator die which, in some embodiments, may be integrated into the interface/translator die 420. The interface/translator die 420 may be an implementation of the translator die 212 of FIG. 2 and/or the translator die 130 of FIG. 1. The interface/translator die 420 may be stacked between the stacked core dies 440 and the interposer 410. The interface/translator die 420 may couple to the interposer via TSV connection points 422 (e.g., 224 of FIG. 2) that have interposer TSV pitch P1. The interface/translator die 420 may pass the TSVs 460 through at the interposer TSV pitch P1 and change the TSV pitch to the interface/translator die 420 and/or stacked core die TSV pitch P using horizontal conductive traces 462 along one surface of the interface/translator die 420 to align with TSV connection points 424. The conductive traces 462 may be an implementation of the conductive traces 136 of FIG. 1, 222 of FIGS. 2, and/or 362 of FIG. 3. The memory package 400 may be an implementation of a side-by-side configuration sometimes called 2.5D memory.

FIG. 5 is a block diagram of a memory package according to an embodiment of the present disclosure. The memory package 500 may be an implementation of the semiconductor device 100 and memory stack 125 of FIG. 1 in some embodiments. The memory package 500 may also be an implementation of the stacked memory device 200 of FIG. 2 in some embodiments. The memory package 500 includes a host 550, such as the host 350 of FIG. 3 and/or the host 450 of FIG. 4, electrically coupled to stacked core dies 540.

The host 550 may include TSV connection points 522 to electrically couple the host 550 to an interface die 540a. The interface die 540a may be an implementation of the stacked die 214a of FIG. 2 and/or the interface die 123 of FIG. 1. The interface die 540 may be stacked between the stacked core dies 540 and the host 550. The interface die 540a is coupled to stacked core dies 540b-540n. The stacked core dies 540b-540n may be an implementation of the stacked core dies 440 of FIG. 4, 340 of FIG. 3, 214 of FIG. 2, and/or the memory stack 125 of FIG. 1. Although FIG. 5 shows the memory package 500 with N core dies, labelled Core Die 0 to Core Die N−1, the stack may have any number of core dies, such as two core dies, 4 core dies, 8 core dies, or any other number. In some embodiments, the TSV connection points 522 (e.g., 224 of FIG. 2) coupling the host 550 with the stacked dies 540a-540n may have a different TSV pitch than the TSVs 560 of the stacked dies 540. For example, the stacked die TSV pitch P may be narrower or wider than the host TSV pitch P1. The TSV pitches P and P1 of memory package 500 may be implementations of the TSV pitches P and P1 of FIG. 4, FIG. 3, FIG. 2, and/or FIG. 1. The difference in TSV pitches may require the use of a translator die 520. The translator die 520 may be an implementation of the translator die 320 of FIG. 3, the translator die 212 of FIG. 2, and/or the translator die 130 of FIG. 1. The translator die 520 may be stacked between the host 550 and the interface die 520. The translator die 520 may pass the TSVs 560 through at the host TSV pitch P1 and change the TSV pitch to the stacked die TSV pitch P using horizontal conductive traces 562 along the top surface to align with TSV connection points 524. The conductive traces 562 may be an implementation of the conductive traces 462 of FIG. 4, the conductive traces 362 of FIG. 3, the conductive traces 222 of FIG. 2, and/or the conductive traces 136 of FIG. 1. The memory package 500 may be an implementation of a configuration sometimes called 3D memory.

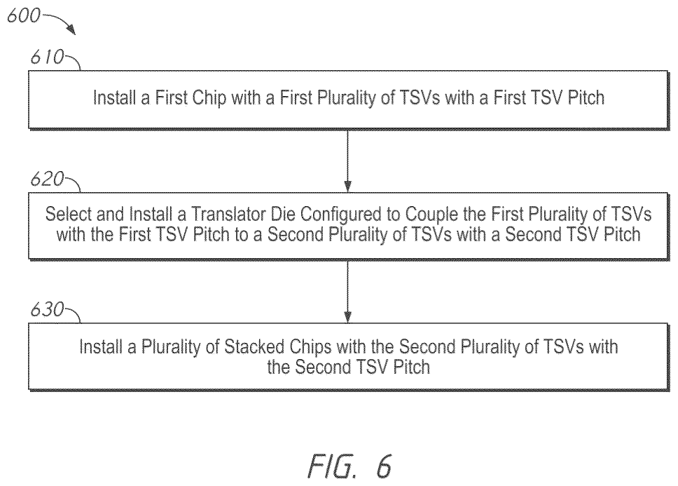

FIG. 6 is a flow chart of a method according to some embodiments of the present disclosure. The method 600 may, in some embodiments, represent the assembly of a memory package such as 125 of FIG. 1, 200 of FIG. 2, 300 of FIG. 3, 400 of FIGS. 4, and/or 500 of FIG. 5.

In some embodiments, the method 600 may include step 610, which describes installing a first chip comprising a first plurality of TSVs with a first TSV pitch. The first chip may be an implementation of the first chip 210 of FIG. 2, interposer 310 of FIG. 3, interposer 410 of FIG. 4, and/or host 550 of FIG. 5. The first TSV pitch may be an implementation of the TSV pitch P1 of FIGS. 1-5.

The method 600 may include step 620, which describes selecting and installing a translator die configured to couple the first plurality of TSVs with the first TSV pitch to a second plurality of TSVs with a second TSV pitch. The translator die may be a translator die such as 130 of FIG. 1, 212 of FIG. 2, 320 of FIGS. 3, and/or 520 of FIG. 5 in some embodiments. In some embodiments, the translator die may be combined with the interface die such as 420 of FIG. 4. The method 600 may include selecting the translator die by matching the first TSV pitch, or the TSV pitch of a first surface of the translator die, with the TSV pitch of the chip on which the translator die will be installed. The first TSV pitch may be an implementation of the first chip TSV pitch P1 of FIGS. 1-5. The translator die may further be selected by matching the TSV pitch on a second surface of the translator die, where the second surface is opposite the first surface, to the TSV pitch of the memory chips that will be stacked directly on to it. The second TSV pitch may be an implementation of stacked die pitch TSV P as in FIGS. 1-5.

The method 600 may include installing the translator die by stacking it directly on to an interposer such as the embodiments shown in FIGS. 3-4. In some embodiments, the translator die may be stacked directly on to the host such as in FIG. 5. In some embodiments, the translator die may be stacked between any dies of a memory stack with differing TSV pitches.

The method 600 may include step 630, which describes installing a plurality of stacked chips with the second plurality of TSVs with the second TSV pitch. The plurality of stacked chips may be an implementation of 125 of FIG. 1, 214 of FIG. 2, 340 of FIG. 3, 440 of FIGS. 4, and/or 540 of FIG. 5 in some embodiments. In some embodiments, there may be more or less stacked dies.

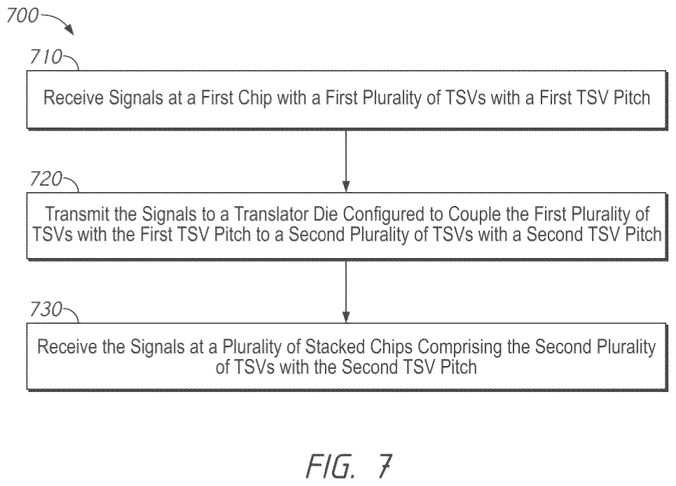

FIG. 7 is a flow chart of a method according to some embodiments of the present disclosure. The method 700 may, in some embodiments, represent the communication of electrical signals within a memory package such as 125 of FIG. 1, 200 of FIG. 2, 300 of FIG. 3, 400 of FIGS. 4, and/or 500 of FIG. 5.

The method 700 may include step 710, which describes receiving signals at a first chip with a first plurality of TSVs with a first TSV pitch. In some embodiments, the method 700 may include sending the signals from a host, such as a processor, coupled to the first chip of the memory package. The first chip may be an implementation of the first chip, 210 of FIG. 2, the interposer 310 of FIG. 3, the interposer 410 of FIG. 4, and/or the host 550 of FIG. 5. The first TSV pitch may be an implementation of the first chip TSV pitch P1 of FIGS. 1-5.

The method 700 may include step 720, which describes transmitting the signals to a translator die configured to couple the first plurality of TSVs with the first TSV pitch to a second plurality of TSVs with a second TSV pitch. The translator die may be a translator die such as 130 of FIG. 1, 212 of FIG. 2, 330 of FIGS. 3, and/or 520 of FIG. 5 in some embodiments. In some embodiments, the translator die may be combined with the interface die such as 420 of FIG. 4. The first TSV pitch may be an implementation of the first chip TSV pitch P1 of FIGS. 1-5. In some embodiments, the signals may be passed through the translator die to stacked chips with the second TSV pitch.

The method 700 may include step 730, which describes receiving the signals at a plurality of stacked chips comprising the second plurality of TSVs with the second TSV pitch. The plurality of stacked dies may be an implementation of 125 of FIG. 1, 214 of FIG. 2, 340 of FIG. 3, 440 of FIGS. 4, and/or 540 of FIG. 5 in some embodiments. In some embodiments, there may be more or less stacked dies.

In some embodiments, the signals may be passed to all stacked chips continuously coupled to the translator die. In some embodiments, the translator die may pass the signals to an interface die, such as 123 of FIG. 1, 214a of FIG. 2, 330 of FIG. 3, 420 of FIGS. 4, and/or 540a of FIG. 5. In some examples, the interface die may pass the signals to all stacked core dies (e.g., 125 of FIG. 1, 214 of FIG. 2, 340 of FIG. 3, 440 of FIGS. 4, and/or 540b-540n of FIG. 5) continuously coupled with the TSVs. In some examples, the interface die may pass the signals to only certain ones of the stacked core dies.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a first die comprising a first set of at least two through-silicon vias (TSVs), the first die having a first TSV pitch;
a second die comprising a second set of at least two TSVs, the second die having a second TSV pitch, wherein the second TSV pitch is different than the first TSV pitch; and
a translator die comprising:
a first side;
a second side; and
a third set of at least two TSVs, the translator die having the first TSV pitch on the first side and the second TSV pitch on the second side, wherein the first side and the second side are opposite sides and wherein the translator die couples the first set of at least two TSVs to the second set of at least two TSVs through the third set of at least two TSVs.

2. The apparatus of claim 1, wherein the translator die further comprises a horizontal conductive trace for each one of the set of at least two TSVs on the second side that changes the first TSV pitch to the second TSV pitch.

3. The apparatus of claim 1, wherein the first die is an interposer configured to couple the translator die to a host.

4. The apparatus of claim 1, wherein the first die is a host.

5. The apparatus of claim 4, wherein the host is a processor.

6. The apparatus of claim 1, wherein the second die is an interface die configured to couple the first die with a plurality of stacked core dies.

7. The apparatus of claim 1, wherein the translator die further comprises an interface die configured to couple the first die with a plurality of stacked core dies.

8. An apparatus comprising:
a host;
an interposer;
a base die with a plurality of TSVs with a first pitch;
at least one stacked memory die with a second plurality of TSVs with a second pitch; and
a translator die configured to couple the first plurality of TSVs with the respective ones of the second plurality of TSVs.

9. The apparatus of claim 8, wherein the at least one stacked memory die is stacked over the translator die and the translator die is stacked over the base die.

10. The apparatus of claim 8, wherein the base die and a host are stacked over the interposer.

11. The apparatus of claim 10, wherein the base die and the host are electrically coupled via the interposer.

12. The apparatus of claim 10, wherein the base die and the host are adjacent to each other.

13. The apparatus of claim 8, wherein the base die and the translator die are combined in a base/translator die.

14. The apparatus of claim 13, wherein the base/translator die is stacked over the interposer and the at least one stacked memory die is stacked over the base/translator die.

15. The apparatus of claim 7, wherein the host is a processor.

16. A method comprising:
receiving signals at a first die comprising a first plurality of TSVs with a first TSV pitch;
transmitting the signals to a translator die configured to couple the first plurality of TSVs with the first TSV pitch to a second plurality of TSVs with a second TSV pitch; and
receiving the signals at a plurality of stacked dies comprising the second plurality of TSVs with the second TSV pitch.

17. The method of claim 16, further comprising transmitting the signals to the first die from a host coupled to the first die.

18. The method of claim 17, wherein the host is adjacent to the plurality of stacked dies.

19. A method comprising:
installing a first chip comprising a first plurality of TSVs with a first TSV pitch;
selecting and installing a translator die configured to couple the first plurality of TSVs with the first TSV pitch to a second plurality of TSVs with a second TSV pitch; and
installing a plurality of stacked chips comprising the second plurality of TSVs with the second TSV pitch.

20. The method of claim 19, wherein selecting the translator die further comprises:
matching the first TSV pitch on a first surface of the translator die; and
matching the second TSV pitch on a second surface of the translator die, wherein the first surface and second surface are opposite of each other.

21. A semiconductor chip comprising:
a set of at least two TSVs;
a first side having a first TSV pitch; and
a second side having a second TSV pitch, wherein the second TSV pitch is different from the first TSV pitch.

22. The semiconductor chip of claim 21, further comprising a horizontal conductive traces for each one of the set of at least two TSVs on the first side, wherein the horizontal conductive traces change the first TSV pitch to the second TSV pitch.

23. The semiconductor chip of claim 21, further comprising a second die with a second set of at least two TSVs having the second TSV pitch, wherein the second die is stacked on the second side and wherein the second die is configured to transmit signals to a plurality of stacked dies.

24. The semiconductor chip of claim 21, wherein the first side is stacked with and coupled to a host.

25. An apparatus comprising:
a host with a first through-silicon via (TSV) and a second TSV with a first TSV pitch;
a first stacked memory die with a third TSV and a fourth TSV with a second TSV pitch; and
a translator die configured to couple the first TSV with the third TSV and to couple the second TSV with the fourth TSV, wherein the first stacked memory die is stacked over the translator die.

26. The apparatus of claim 25, wherein the translator die is stacked over the host.

27. The apparatus of claim 25, wherein the translator die comprises:
a fifth TSV and a sixth TSV with the first TSV pitch;
a first horizontal trace along a surface of the translator die; and
a second horizontal trace along the surface of the translator die, wherein a distance between the first and second horizontal traces changes from the first TSV pitch to the second TSV pitch.

28. The apparatus of claim 25, wherein the host comprises a processor.
